(19) United States
(12) Patent Application Publication
(10) Pub. No.: US 2024/0355774 A1
(43) Pub. Date: Oct. 24, 2024

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventors: Nozomi SAITO, Tokyo (JP); Yuki YANO, Tokyo (JP)

(73) Assignee: Mitsubishi Electric Corporation, Tokyo (JP)

(21) Appl. No.: 18/683,482

(22) PCT Filed: Nov. 18, 2021
(86) PCT No.: PCT/JP2021/042363

§ 371 Date: Feb. 13, 2024

(51) Int. Cl. H01L 23/00; H01L 23/31; H01L 23/498; H01L 25/065

(52) U.S. Cl. CPC H01L 24/40; H01L 23/3171; H01L 23/49822; H01L 24/32; H01L 24/73; H01L 24/48; H01L 24/84; H01L 25/0655; H01L 2224/32225; H01L 2224/40155; H01L 2224/40475; H01L 2224/48155; H01L 2224/73263; H01L 2224/84007

(57) ABSTRACT

The object is to provide a technology for enabling reduction of adhesion of a bonding material to a particular electrode. A semiconductor device includes: a semiconductor element with a surface including a first electrode and a second electrode; a protective film formed on the surface of the semiconductor element and having insulating properties, the protective film exposing the first electrode and the second electrode; a metal lead electrode bonded to the first electrode exposed from the protective film; and a bonding material with which the first electrode exposed from the protective film is bonded to the metal lead electrode. The metal lead electrode includes an abutment portion being a protrusion abutting the protective film and blocking between the bonding material and the second electrode in a cross-sectional view.

### TECHNICAL FIELD

The present disclosure relates to a semiconductor device and a method for manufacturing the semiconductor device.

### BACKGROUND ART

To pursue larger currents, longer life, and higher reliability, what has been proposed are semiconductor devices such as power semiconductor devices each with a structure including a plate-shaped metal lead electrode instead of a metal wire bond. In a step of melting a bonding material with which a metal lead electrode is bonded to a surface electrode of a semiconductor element in manufacturing steps of these structures, however, the bonding material sometimes flies off to the surroundings due to volatilization of an activator contained in the bonding material or ejection of bubbles in the bonding material. This sometimes causes the bonding material to adhere to a control electrode on the semiconductor element, thus making it difficult to wire bond the control electrode in a latter wiring step. Consequently, a problem of worsening the reliability and the productivity has occurred.

To address this, a semiconductor device including a metal lead electrode bonded to a main electrode through a bonding material and including an electrical connection piece that is a protrusion is proposed (e.g., Patent Document 1). Since the electrical connection piece can inhibit the bonding material from flying off under such a technology, a decrease in the reliability of the semiconductor device can be inhibited.

### PRIOR ART DOCUMENT

### Patent Document

Patent Document 1: WO2019/167254

### SUMMARY

### Problem to be Solved by the Invention

However, there is a crevice under the electrical connection piece, which still causes a problem in that the bonding material flies off and adheres to an electrode such as a control electrode.

The present disclosure has been conceived in view of the problem, and has an object of providing a technology for enabling reduction of adhesion of a bonding material to a particular electrode.

### Means to Solve the Problem

A semiconductor device according to the present disclosure includes: a semiconductor element with a surface including a first electrode and a second electrode that are separated from each other; a protective film formed on the surface of the semiconductor element and having insulating properties, the protective film exposing the first electrode and the second electrode; a metal lead electrode bonded to the first electrode exposed from the protective film; and a bonding material with which the first electrode exposed from the protective film is bonded to the metal lead electrode, wherein the metal lead electrode includes an abutment portion being a protrusion abutting the protective film and blocking between the bonding material and the second electrode in a cross-sectional view.

### Effects of the Invention

According to the present disclosure, the metal lead electrode includes an abutment portion being a protrusion abutting the protective film and blocking between the bonding material and the second electrode in a cross-sectional view. This structure can reduce adhesion of a bonding material to a particular electrode.

The objects, features, aspects, and advantages of the present disclosure will become more apparent from the following detailed description and the accompanying drawings.

### BRIEF DESCRIPTION OF DRAWINGS

FIG. 1 is a plan view schematically illustrating a structure of a semiconductor device according to Embodiment 1.

FIG. 2 is a cross-sectional view of a part of the semiconductor device according to Embodiment 1.

FIG. 3 is a plan view of the part of the semiconductor device according to Embodiment 1.

FIG. 4 is a cross-sectional view of a part of a relevant semiconductor device.

FIG. 5 is a cross-sectional view of a part of a semiconductor device according to Embodiment 2.

FIG. 6 is a cross-sectional view of a part of a semiconductor device according to Embodiment 3.

FIG. 7 is a plan view of the part of the semiconductor device according to Embodiment 3.

FIG. 8 is a cross-sectional view of a part of a semiconductor device according to Embodiment 4.

FIG. 9 is a cross-sectional view of a part of a semiconductor device according to Embodiment 5.

### DESCRIPTION OF EMBODIMENTS

Hereinafter, Embodiments will be described with reference to the accompanying drawings. The features to be described in Embodiments below are mere exemplifications, and all of the features are not necessarily essential. In the description below, identical constituent elements in a plurality of Embodiments will be denoted by the same or similar reference numerals, and the different constituent elements will be mainly described. In the following description, a particular position and a particular direction such as “up”, “down”, “left”, “right”, “front”, or “back” need not always coincide with an actual position and an actual direction.

### Embodiment 1

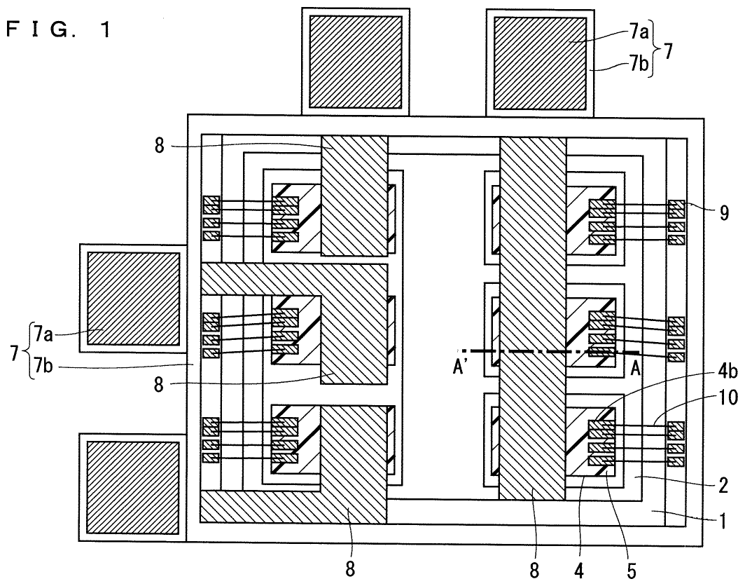

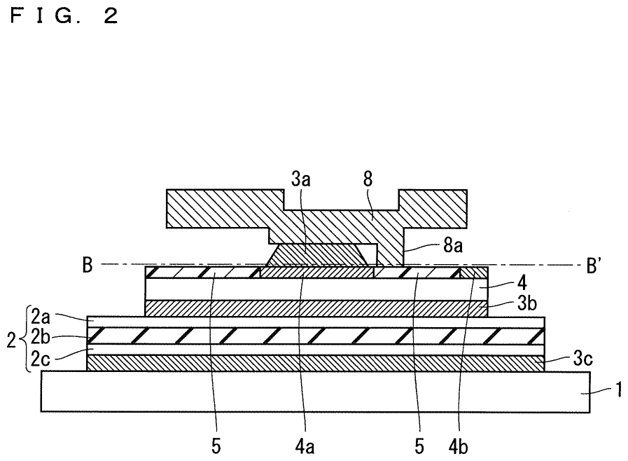

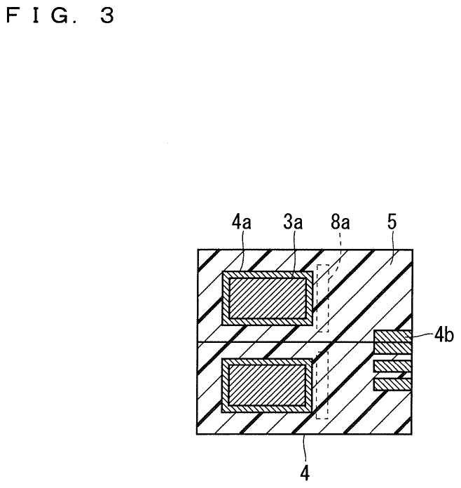

FIG. 1 is a plan view schematically illustrating a structure of a semiconductor device according to Embodiment 1. FIG. 2 is a cross-sectional view taken along the line A-A′ of FIG. 1. FIG. 3 is a plan view taken along the line B-B′ of FIG. 2.

The semiconductor device according to Embodiment 1 includes a base plate 1, a circuit board 2, bonding materials 3a, 3b, and 3c, semiconductor elements 4, protective films 5, a casing 7, metal lead electrodes 8, external signal terminals 9, metal wire 10, and a sealant that is not illustrated.

The base plate 1 is made of a material with superior thermal conductivity, for example, an aluminum alloy or copper.

The circuit board 2 in FIG. 2 includes circuit patterns 2a and 2c, and an insulating layer 2b. The insulating layer 2b is made of, for example, a ceramic with superior thermal conductivity such as aluminum nitride or silicon nitride, or a resin. The circuit pattern 2a is disposed on an upper surface of the insulating layer 2b, and the circuit pattern 2c is disposed on a lower surface of the insulating layer 2b. The circuit patterns 2a and 2c are made of a material with superior thermal conductivity, for example, an aluminum alloy or copper.

The bonding materials 3c bonds the base plate 1 to the circuit pattern 2c. The bonding material 3b bonds the circuit pattern 2a of the circuit board 2 to the semiconductor element 4 mounted on the circuit board 2. The bonding materials 3b and 3c, and the bonding material 3a to be described later are made of, for example, solder or soft solder.

A surface electrode 4a that is a first electrode is separated from a control electrode 4b that is a second electrode. The semiconductor element 4 has a surface including the surface electrode 4a and the control electrode 4b. The surface electrode 4a is a main electrode through which a relatively large current flows. The control electrode 4b is an electrode for controlling the semiconductor element 4 with a signal. The surface electrode 4a and the control electrode 4b are made of, for example, at least one of nickel (Ni) or gold (Au). When the semiconductor element 4 includes an aluminum (Al)-silicon (Si) layer, the surface electrode 4a and the control electrode 4b are disposed on the Al—Si layer.

The semiconductor element 4 according to Embodiment 1 is, though not limited to, an insulated-gate bipolar transistor (IGBT) but may be, for example, a reverse conducting IGBT, a metal-oxide semiconductor field-effect transistor (MOSFET), a Schottky barrier diode (SBD), or a PN junction diode (PND). The semiconductor element 4 may be made of, for example, normal silicon (Si), or a wide bandgap semiconductor such as silicon carbide (SiC), gallium nitride (GaN), or diamond. The semiconductor element 4 made of a wide bandgap semiconductor can stably operate at high temperatures and high voltages, and accelerate the switching speed. The number of the semiconductor elements 4 is, though not limited to, six in FIG. 1 but is determined according to the usage of the semiconductor device.

The protective film 5 in FIG. 2 is disposed on the surface of the semiconductor element 4 including the surface electrode 4a and the control electrode 4b, and exposes the surface electrode 4a and the control electrode 4b. The protective film 5 has insulating properties, and is made of, for example, polyimide.

The bonding material 3a bonds the metal lead electrodes 8 to the surface electrodes 4a exposed from the protective films 5. Thus, the metal lead electrodes 8 are bonded to the surface electrodes 4a exposed from the protective films 5. Portions of the metal lead electrodes 8 facing the surface electrodes 4a protrude toward the surface electrodes 4a, and include abutment portions 8a. The abutment portions 8a are protrusions that abut the protective films 5 and block between the bonding material 3a and the control electrodes 4b through the abutment in a cross-sectional view (see FIG. 2). Since the bonding material 3a coincides in position with the surface electrodes 4a, the abutment portions 8a substantially block between the surface electrodes 4a and the control electrodes 4b in a cross-sectional view.

Each of the abutment portions 8a illustrated by dotted lines in the plan view of FIG. 3 principally blocks between the bonding material 3a and the control electrode 4b. Connecting a part of the metal lead electrodes 8 to the circuit pattern 2a of the circuit board 2 may form a circuit, which is not illustrated.

The casing 7 in FIG. 1 includes external electrodes 7a and casing resin parts 7b. The external electrodes 7a are electrically connected to the metal lead electrodes 8. The metal lead electrodes 8 may be a part of the external electrodes 7a, or parts different from the external electrodes 7a. When the metal lead electrodes 8 are a part of the external electrodes 7a, the metal lead electrodes 8 may be formed by extending the external electrodes 7a inserted in advance into the casing resin parts 7b, up to on the semiconductor elements 4. When the metal lead electrodes 8 are parts different from the external electrodes 7a, the metal lead electrodes 8 may be bonded to the external electrodes 7a inserted in advance into the casing resin parts 7b by, for example, solder joints, welding, or ultrasonic bonding.

The casing resin parts 7b surround the semiconductor elements 4 and the metal lead electrodes 8, and the space around the semiconductor elements 4 and the metal lead electrodes 8. A sealant that is not illustrated is provided in the space. Part of the external electrodes 7a is exposed from the casing resin parts 7b outside the space. An external apparatus connected to the outside part of the external electrodes 7a is electrically connected to the semiconductor elements 4 through the external electrodes 7a and the metal lead electrodes 8. The sealant is made of, for example, a resin.

The external signal terminals 9 are disposed in the casing resin parts 7b, similarly to the external electrodes 7a. Electrically connecting the external signal terminal 9 to the control electrode 4b through the metal wire 10 forms a signal circuit. The metal wire 10 is made of a metal high in thermal conductivity and electric conductivity, for example, aluminum.

### [Manufacturing Method]

Next, an example method for manufacturing the semiconductor device according to Embodiment 1 will be described.

### [Procedure S1]

During the process of forming the semiconductor elements 4, the surface electrode 4a and the control electrode 4b are formed on each of the semiconductor elements 4. Then, the protective film 5 is formed on the Al—Si layer of the semiconductor element 4 except the surface electrode 4a and the control electrode 4b to protect the Al—Si layer. Since the surface electrode 4a and the control electrode 4b are subjected to metal joining or ultrasonic bonding in a latter step, the protective film 5 made of, for example, polyimide is not formed on the surface electrode 4a and the control electrode 4b. A portion of the protective film 5 to be abutted by the abutment portion 8a of the metal lead electrode 8 in a latter step may be thicker than the other portions.

### [Procedure S2]

The base plate 1, the circuit board 2, and the semiconductor elements 4 are bonded together through the bonding materials 3b and 3c such as plate solder, soldering paste, or soft solder. Generally, solder is often used as the bonding materials 3b and 3c. The bonding in the procedure S2 is performed by heating the bonding materials 3b and 3c, for example, solder to be applied, to a temperature exceeding the melting point. The bonding materials 3b and 3c may be components molded in advance, for example, plate solder, or a component such as soldering paste to be applied through, for example, screen printing or a dispenser.

### [Procedure S3]

The casing 7 is bonded to the base plate 1. For example, after a silicone-based or epoxy-based adhesive that is not illustrated is applied to a bonding surface of the base plate 1 below the casing resin parts 7b, a load is applied to the base plate 1 on which the semiconductor elements 4 are mounted in the procedure S2, so that the casing resin parts 7b are bonded in tight contact with the base plate 1. Fastening the casing 7 to the base plate 1 is not limited to this. For example, the casing resin parts 7b and the base plate 1 may be secured to each other through self-tapping screws that are not illustrated. Alternatively, after the casing resin parts 7b are fastened to the base plate 1 by, for example, a clamp fixture, they may be fastened to each other by heating an adhesive.

### [Procedure S4]

The metal lead electrodes 8 are disposed on the semiconductor elements 4 to bond the surface electrodes 4a to the metal lead electrodes 8. Before this bonding, first, the abutment portions 8a of the metal lead electrodes 8 are disposed in abutment on the protective films 5 on the surfaces of the semiconductor elements 4. These abutment portions 8a block between the bonding material 3a and the control electrodes 4b. The protrusions of the abutment portions 8a may be formed by, for example, press working in a process of molding the metal lead electrodes 8, or folding as described in Embodiment 2.

Simultaneously with abutment of the abutment portions 8a to the protective films 5, the bonding material 3a for bonding the surface electrodes 4a of the semiconductor elements 4 to the metal lead electrodes 8 is supplied. Before the metal lead electrodes 8 are disposed on the semiconductor elements 4, the bonding material 3a may be supplied on the surface electrodes 4a of the semiconductor elements 4 in dispense application or screen printing. Alternatively, the bonding material 3a may be supplied from at least one through hole formed in advance in the metal lead electrodes 8, after the metal lead electrodes 8 are disposed on the semiconductor element 4 as described in Embodiments 4 and 5. Alternatively, the bonding material 3a may be supplied on the surface electrodes 4a of the semiconductor elements 4 as reserve solder in, for example, dispense application or screen printing in the procedure S2.

After disposing the metal lead electrodes 8 and supplying the bonding material 3a, the metal lead electrodes 8 are bonded to the surface electrodes 4a of the semiconductor elements 4 by heating the bonding material 3a to a temperature exceeding the melting point similarly to the procedure S2. Although the melting point of the bonding material 3a is preferably lower than that of the bonding material 3b, the melting points may be equivalent.

### [Procedure S5]

The control electrodes 4b on the semiconductor elements 4 and the external signal terminals 9 are wire bonded through the metal wire 10 to be electrically connected to the signal circuit for controlling the semiconductor elements 4. For example, ultrasonic bonding is used for the wire bonding.

### [Procedure S6]

The sealant that is not illustrated seals the space surrounded by the casing resin parts 7b in the structure assembled through the procedures S1 to S5. The sealant is made of, though not limited to, silicone gel or an epoxy resin, but may be made of any material having desired properties on, for example, a modulus of elasticity, heat resistance, adhesiveness, and a thermal expansion coefficient. The assembled structure is put into, for example, a curing furnace so that the sealant is cured as necessary. Consequently, the semiconductor device is completed. Then, the semiconductor device is inspected on, for example, necessary electrical characteristics.

### Conclusion of Embodiment 1

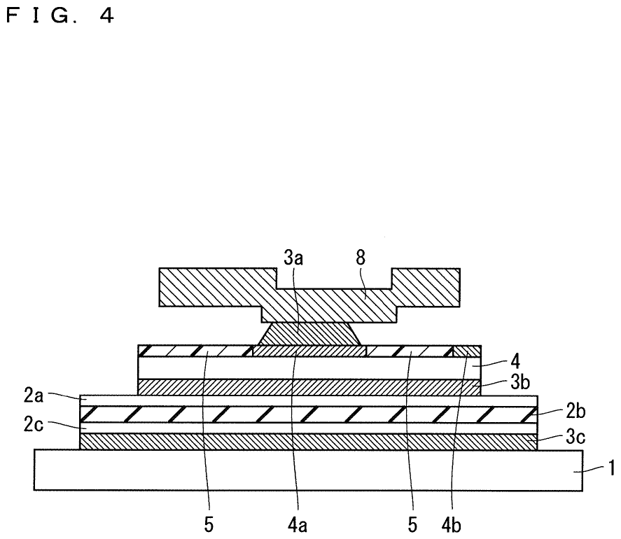

FIG. 4 is a cross-sectional view illustrating a structure of a semiconductor device relevant to the semiconductor device according to Embodiment 1 (hereinafter referred to as a “relevant semiconductor device”), and corresponds to FIG. 2. In the procedure S4 of melting the bonding material 3a, a part of the bonding material 3a sometimes flies off due to volatilization of an activated component in the bonding material 3a (e.g., flux in plate solder) or ejection of bubbles in the bonding material 3a.

Since the relevant semiconductor device does not include the abutment portions 8a according to Embodiment 1, the part of the bonding material 3a that has flied off sometimes adheres to the control electrodes 4b. This consequently makes it difficult to wire bond the control electrodes 4b in the wiring step of the procedure S5, and causes a problem of worsening the reliability and the productivity.

In contrast, since the abutment portions 8a block between the bonding material 3a and the control electrodes 4b in a cross-sectional view according to Embodiment 1, adhesion of the bonding material 3a to the control electrodes 4b can be reduced. Consequently, we can expect that semiconductor devices of long life can be stably manufactured.

### Embodiment 2

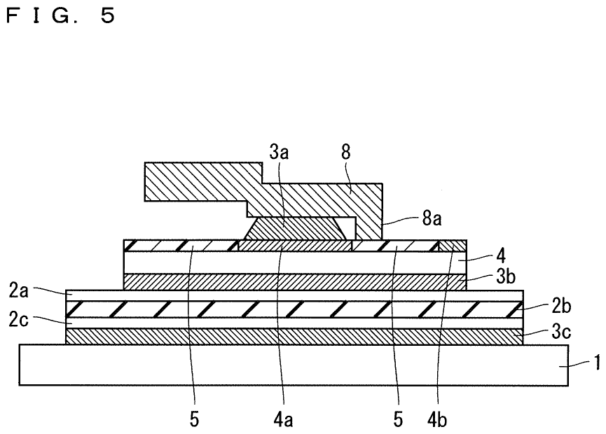

FIG. 5 is a cross-sectional view illustrating a structure of a semiconductor device according to Embodiment 2, and corresponds to FIG. 2. Each of the abutment portions 8a according to Embodiment 1 is formed in the center of the metal lead electrode 8 in a surface direction as illustrated in FIG. 2. The abutment portion 8a according to Embodiment 2 is formed at an end (at a right end in FIG. 5) of the metal lead electrode 8 in the surface direction as illustrated in FIG. 5. The basic structure other than this is identical to that according to Embodiment 1.

The aforementioned structure according to Embodiment 2 can reduce adhesion of the bonding material 3a to the control electrodes 4b similarly to Embodiment 1. Furthermore, since the abutment portions 8a can be formed by folding that is a relatively easy process, we can expect reduction in the manufacturing cost.

### Embodiment 3

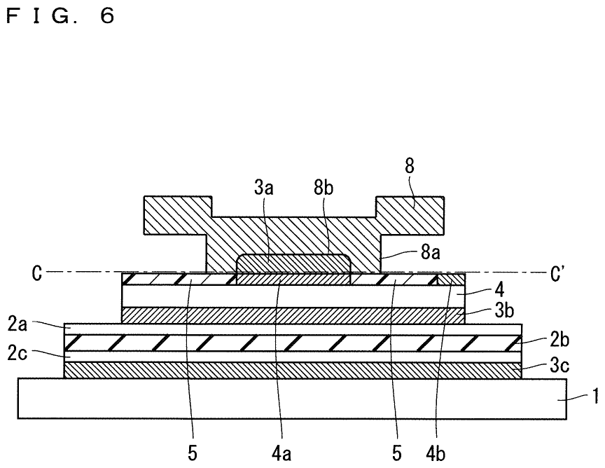

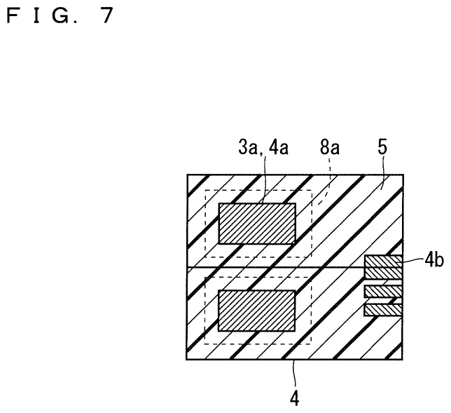

FIG. 6 is a cross-sectional view illustrating a structure of a semiconductor device according to Embodiment 3, and corresponds to FIG. 2. FIG. 7 is a plan view taken along the line C-C′ of FIG. 6.

As illustrated in FIG. 6, each of the metal lead electrodes 8 according to Embodiment 3 includes a dent 8b in a lower portion of the metal lead electrode 8. The dent 8b in the example of FIG. 6 is domical, which is not limited to this.

The dent 8b contains the bonding material 3a. In the example of FIG. 6, the dent 8b is filled with the bonding material 3a. The edge of the dent 8b abuts the protective film 5, and includes the abutment portion 8a.

Each of the edges of the dents 8b illustrated by the dotted lines in the plan view of FIG. 3 encloses the whole perimeter of the bonding material 3a in a plan view. The abutment portions 8a completely block between the bonding material 3a and the control electrodes 4b. The metal lead electrode 8 may have a through hole that goes from its upper surface to the bottom of the dent 8b. The basic structure other than this is identical to that according to Embodiment 1.

The structure according to Embodiment 3 can reduce adhesion of the bonding material 3a to the control electrodes 4b similarly to Embodiment 1. Furthermore, the edges of the dents 8b each enclosing the whole perimeter of the bonding material 3a can reduce the bonding material 3a flying off and adhering to not only the control electrodes 4b but also other portions (e.g., the circuit board 2 or the other semiconductor elements 4). This can consequently inhibit a decrease in the insulating performance.

Furthermore, the contact area between the metal lead electrodes 8 and the bonding material 3a can be increased. This can reduce a current density in using the semiconductor device, and inhibit a decrease in the reliability due to locally generated heat.

### Embodiment 4

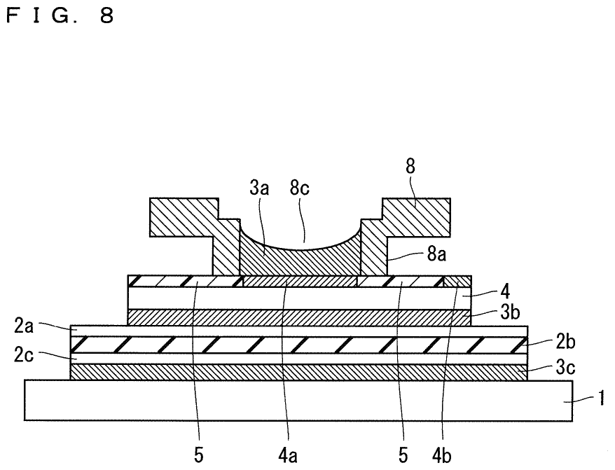

FIG. 8 is a cross-sectional view illustrating a structure of a semiconductor device according to Embodiment 4, and corresponds to FIG. 2.

As illustrated in FIG. 8, each of the metal lead electrodes 8 according to Embodiment 4 includes a through hole 8c containing the bonding material 3a. Furthermore, the edge of the through hole 8c abuts the protective film 5, and encloses the whole perimeter of the bonding material 3a in a plan view, similarly to the edge of the dent 8b according to Embodiment 3. The through hole 8c may be rectangular or circular in a plan view to correspond to the shape of the surface electrode 4a of the semiconductor element 4. The area of the through hole 8c in a plan view may be larger than that of the surface electrode 4a of the semiconductor element 4. The basic structure other than this is identical to that according to Embodiment 1.

The structure according to Embodiment 4 can reduce adhesion of the bonding material 3a not only to the control electrodes 4b similarly to Embodiment 3 but also to portions other than the control electrodes 4b. Since the metal lead electrodes 8 can have the through holes 8c that are relatively large, the bonding material 3a can be supplied from the through holes 8c of the metal lead electrodes 8 in dispense application after the metal lead electrodes 8 are disposed on the semiconductor elements 4. This can consequently facilitate supplying the bonding material 3a.

To inspect whether the bondability between the metal lead electrodes 8 and the bonding material 3a is normal, a nondestructive inspection on the bondability has been conventionally performed by ultrasonic flaw detection or by X-ray in some cases. In contrast, the bondability can be visually inspected based on whether the bonding material 3a wets up the wall surfaces of the through holes 8c of the metal lead electrodes 8 in Embodiment 4. This can simplify the inspection on the bondability. Thus, we can expect omission of the inspection by ultrasonic flaw detection or by X-ray.

### Embodiment 5

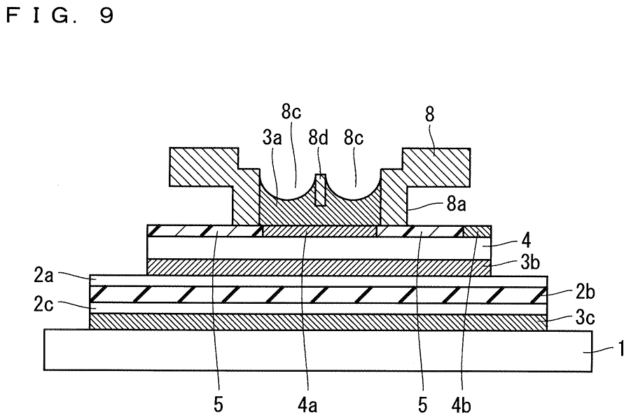

FIG. 9 is a cross-sectional view illustrating a structure of a semiconductor device according to Embodiment 5, and corresponds to FIG. 2.

As illustrated in FIG. 9, the metal lead electrodes 8 according to Embodiment 5 include a plurality of through holes 8c containing the bonding material 3a. The metal lead electrodes 8 include partitions 8d that partition the plurality of through holes 8c and are in contact with the bonding material 3a. The number, widths, and positions in a height direction of the partitions 8d are any. The basic structure other than these is identical to that according to Embodiment 4.

The structure according to Embodiment 4 can reduce adhesion of the bonding material 3a not only to the control electrodes 4b similarly to Embodiment 3, but also to portions other than the control electrodes 4b. Furthermore, the through holes 8c can facilitate supplying the bonding material 3a and simplify the inspection on the bondability similarly to Embodiment 4.

Furthermore, the partitions 8d can increase the contact area between the metal lead electrodes 8 and the bonding material 3a. This can reduce the current density in using the semiconductor device, and inhibit a decrease in the reliability due to locally generated heat. The partitions 8d can also reduce the amount of the bonding material 3a to be used.

Embodiments and modifications can be freely combined, and can be appropriately modified or omitted.

The foregoing description is in all aspects illustrative and not restrictive. Therefore, numerous modifications and variations that have not yet been exemplified will be devised.

### EXPLANATION OF REFERENCE SIGNS

2 circuit board, 3a bonding material, 4 semiconductor element, 4a surface electrode, 4b control electrode, 5 protective film, 8 metal lead electrode, 8a abutment portion, 8b dent, 8c through hole, 8d partition.

1. A semiconductor device, comprising:
a semiconductor element with a surface including a first electrode and a second electrode that are separated from each other;
a protective film formed on the surface of the semiconductor element and having insulating properties, the protective film exposing the first electrode and the second electrode;
a metal lead electrode bonded to the first electrode exposed from the protective film; and
a bonding material with which the first electrode exposed from the protective film is bonded to the metal lead electrode,
wherein the metal lead electrode includes an abutment portion being a protrusion abutting the protective film and blocking between the bonding material and the second electrode in a cross-sectional view.

2. The semiconductor device according to claim 1, further comprising
a circuit board on which the semiconductor element is mounted, the circuit board being bonded to a part of the metal lead electrode.

3. The semiconductor device according to claim 1,
wherein the abutment portion is formed at an end of the metal lead electrode in a surface direction.

4. The semiconductor device according to claim 1,
wherein the metal lead electrode includes a dent containing the bonding material, and
an edge of the dent abuts the protective film and includes the abutment portion.

5. The semiconductor device according to claim 1,
wherein the metal lead electrode includes at least one through hole containing the bonding material, and
an edge of the at least one through hole abuts the protective film and includes the abutment portion.

6. The semiconductor device according to claim 5,
wherein the number of the at least one through hole is plural, and
the metal lead electrode includes partitions partitioning the plural through holes and being in contact with the bonding material.

7. A method for manufacturing the semiconductor device according to claim 1, the method comprising
melting the bonding material with the abutment portion abutting the protective film to bond the first electrode to the metal lead electrode through the bonding material.
